(19) United States
(12) Patent Application Publication
(10) Pub. No.: US 2025/0391744 A1
(43) Pub. Date: Dec. 25, 2025

(54) SEMICONDUCTOR DEVICE INCLUDING A COINED DIEPAD

(71) Applicant: Infineon Technologies AG, Neubiberg (DE)

(72) Inventors: Aira Lourdes Baring VILLAMOR, Melaka (MY); Chai Chee LEE, Melaka (MY); Edward MYERS, Unterhaching (DE); Uwe SCHINDLER, Reichenbach (DE); Frank SINGER, Regenstauf (DE)

(73) Assignee: Infineon Technologies AG, Neubiberg (DE)

(21) Appl. No.: 19/224,997

(22) Filed: Jun. 2, 2025

(30) Foreign Application Priority Data
Jun. 19, 2024 (DE) 10 2024 117 263.0

(51) Int. Cl. H01L 23/495; H01L 21/48; H01L 21/56; H01L 23/31

(52) U.S. Cl. CPC H01L 23/49503; H01L 21/4842; H01L 21/565; H01L 23/3114; H01L 23/49562

(57) ABSTRACT

A semiconductor device is disclosed. In one example, the semiconductor device includes a diepad having a top surface and a bottom surface as well as a semiconductor die mounted on the top surface of the diepad. The bottom surface of the diepad includes at least two coined edge regions and an uncoined region. The diepad includes an uncoined tie bar arranged between two coined edge regions of the bottom surface. An area of the top surface is larger than an area of the uncoined region of the bottom surface.

### CROSS-REFERENCE TO RELATED APPLICATION

This Utility Patent application claims priority to German Patent Application No. 10 2024 117 263.0 filed Jun. 19, 2024, which is incorporated herein by reference.

### TECHNICAL FIELD

The present disclosure relates to semiconductor devices including coined diepads and associated manufacturing methods.

### BACKGROUND

Semiconductor devices may include diepads for mounting semiconductor dies, wherein the size of a diepad may be dictated by footprint compatibility requirements. A mounting surface of the diepad may therefore be limited to a specific mounting area such that only semiconductor dies up to a certain size may be mounted on the diepad. In view of the above, it may be desirable to provide diepads and semiconductor devices having a sufficient mounting area while at the same time meeting existing footprint compatibility requirements. In addition, it may be desirable to provide simple and cost efficient methods for manufacturing the diepads and semiconductor devices.

### SUMMARY

An aspect of the present disclosure relates to a semiconductor device. The semiconductor device comprises a diepad including a top surface and a bottom surface. The semiconductor device further comprises a semiconductor die mounted on the top surface of the diepad. The bottom surface of the diepad comprises at least two coined edge regions and an uncoined region. The diepad comprises an uncoined tie bar arranged between two coined edge regions of the bottom surface. An area of the top surface is larger than an area of the uncoined region of the bottom surface.

A further aspect of the present disclosure relates to a method. The method comprises a step of providing a metal panel. The method further comprises a step of forming multiple first openings in the metal panel to form a leadframe panel comprising multiple diepads, wherein the multiple diepads are arranged in a row, wherein two adjacent diepads are separated by two first openings arranged side by side and connected by a tie bar between the two first openings. The method further comprises a step of coining edge regions of bottom surfaces of the diepads, wherein material of the diepads is pressed into an area of the first openings. The method further comprises a step of forming multiple second openings at the position of the multiple first openings so as to remove the material pressed into the area of the first openings, wherein each second opening is wider than the first openings, wherein the two adjacent diepads are still connected by the tie bar.

A further aspect of the present disclosure relates to a method. The method comprises a step of providing a leadframe panel comprising multiple diepads arranged in multiple rows. Each diepad includes a top surface and a bottom surface. The bottom surface of each diepad comprises a coined edge region and an uncoined region. An area of the top surface is larger than an area of the uncoined region of the bottom surface. The method further comprises a step of mounting multiple semiconductor dies on the top surfaces of the diepads. The method further comprises a step of attaching multiple clips on top of the semiconductor dies. The method further comprises a step of performing an encapsulation process, wherein multiple bars made of an encapsulation material are formed, wherein each bar encapsulates a row of diepads. The method further comprises a step of singulating the multiple bars into multiple semiconductor packages.

### BRIEF DESCRIPTION OF THE DRAWINGS

Devices and methods in accordance with the disclosure are described in more detail below based on the drawings. The elements of the drawings are not necessarily to scale relative to each other. Similar reference numerals may designate corresponding similar parts. The technical features of the various illustrated examples may be combined unless they exclude each other and/or can be selectively omitted if not described to be necessarily required.

FIG. 1 includes FIGS. 1A to 1C illustrating different views of a diepad 100 which may be included in a semiconductor device in accordance with the disclosure.

FIG. 2 includes FIGS. 2A and 2B illustrating different views of a semiconductor device 200 in accordance with the disclosure.

FIG. 3 includes FIGS. 3A and 3B illustrating different views of a semiconductor device 300 in accordance with the disclosure.

FIG. 4 illustrates a flowchart of a method in accordance with the disclosure.

FIG. 5 includes FIGS. 5A to 5E schematically illustrating a method in accordance with the disclosure.

FIG. 6 illustrates a flowchart of a method in accordance with the disclosure.

FIG. 7 includes FIGS. 7A to 7F schematically illustrating a method for manufacturing a semiconductor device 700 in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

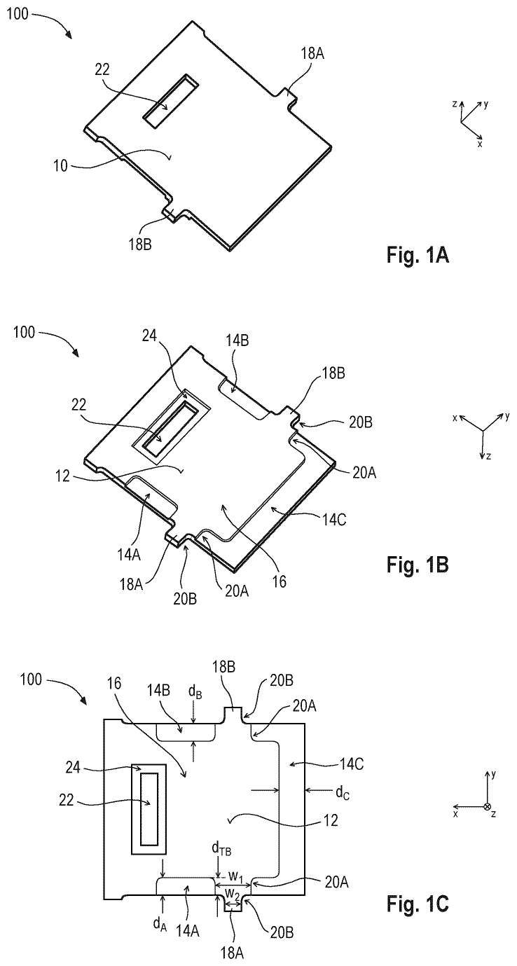

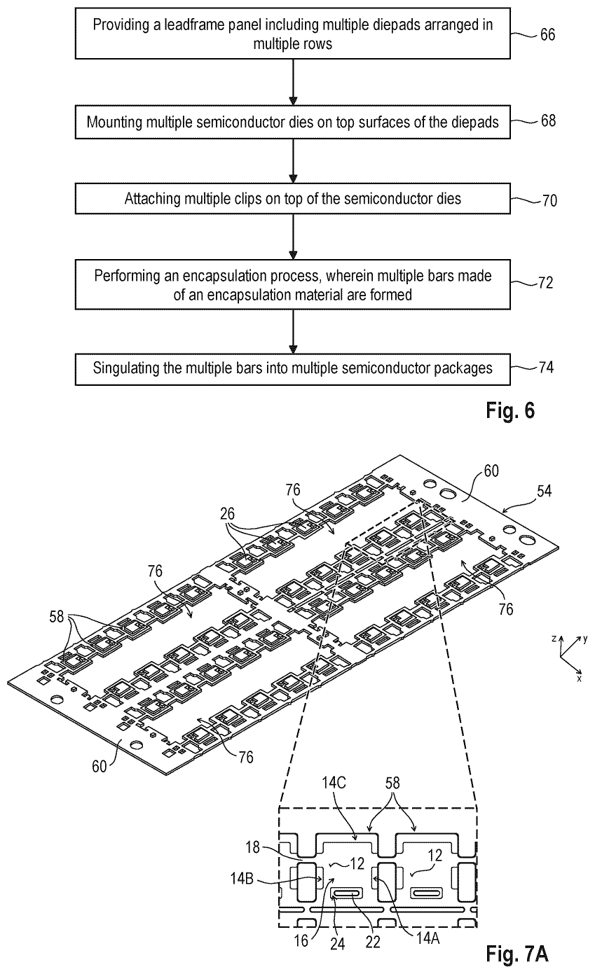

Referring now to FIGS. 1A to 1C, different views of a diepad 100 are shown which may be included in a semiconductor device in accordance with the disclosure. It is noted that an exemplary method for manufacturing one or multiple of such diepads is e.g. shown and described in connection with FIG. 5. The diepad 100 may include or may be made of a metal or a metal alloy. For example, the diepad 100 may include a core material including at least one of copper, copper alloy, aluminum, aluminum alloy, or the like. Optionally, the diepad 100 may be plated with at least one plating material which may, for example, include at least one of nickel, nickel-phosphorous, nickel-nickel-phosphorous, copper, silver, or the like. The plating material may cover the entire diepad 100 (or its core material) or only selected portions of it. It is to be understood that the core material and the plating material of the diepad 100 may depend on a type of semiconductor die that is to be mounted on the diepad 100 and/or a material of an electrical connection element (e.g. wire, ribbon, clip, or the like) that is to be connected to the diepad 100.

The diepad 100 may include a top surface 10 and an opposing bottom surface 12. The bottom surface 12 of the diepad 100 may include at least two coined edge regions 14 and an uncoined region 16. When measured in a direction perpendicular to the top surface 10 or bottom surface 12, i.e. in the z-direction, a thickness of the coined edge regions 14 may be smaller than a thickness of the uncoined region 16. In the illustrated example, the bottom surface 12 may include an exemplary number of three coined edge regions 14A to 14C. In further examples, the number of coined edge regions 14 may be two or even higher than three. In the exemplary top view of the bottom surface 12 shown in FIG. 1C, the bottom surface 12 of the diepad 100 may include a first coined edge region 14A arranged at the lower side of the diepad 100 and a second coined edge region 14B arranged at the upper side of the diepad 100 opposite the lower side. In the shown case, each of the coined edge regions 14A and 14B may substantially have the shape of a rectangle. In further examples, the shape or form of the coined edge regions 14 may differ. In one exemplary embodiment, the bottom surface 12 may only have two coined regions 14A and 14B, while the region 14C shown in FIG. 1C may be an uncoined region, i.e. its thickness may be the same as that of the uncoined region 16.

The bottom surface 12 of the diepad 100 may optionally include a third coined edge region 14C arranged at the right side of the diepad 100 in FIG. 1C and connecting the lower side and the upper side of the diepad 100. In the illustrated example, the third coined edge region 14C may extend along the entire right side of the diepad 100 and partially along the lower side and the upper side of the diepad 100. The third coined edge region 14C may thus have the shape of the letter “U” opened to the left. The coined edge regions 14A to 14C may be separated by portions of the uncoined region 16.

Since the bottom surface 12 of the diepad 100 may include coined edge regions 14A to 14C, but the top surface 10 does not, an area of the top surface 10 may be larger than an area of the uncoined region 16 of the bottom surface 12. In the illustrated example, the coined edge regions 14A to 14C may surround the uncoined region 16 at three sides of the diepad 100. In a further example, the diepad 100 may not necessarily include the third coined edge region 14C, i.e. the coined edge regions 14A and 14B may be arranged at two opposing sides of the diepad 100, while the other two sides of the diepad 100 may be free from coined edge regions.

When measured in the z-direction, a thickness of the coined edge regions 14A to 14C may be in a range from about 60% to about 90% (and more particular in a range from about 85% to about 90%) of a thickness of the uncoined region 16. In other words, a coining depth may be in a range from about 10% to about 40% (and more particular in a range from about 10% to about 15%) of a thickness of the uncoined region 16 when measured in the z-direction. A dimension d_{A} of the first coined edge region 14A measured in the y-direction may be in a range from about 0.2 mm to about 0.6 mm. A dimension d_{B} of the second coined edge region 14B measured in the y-direction may be similar to the dimension d_{A}. A dimension d_{C} of the third coined edge region 14C measured in the x-direction may be in a range from about 0.4 mm to about 0.8 mm. All these three dimensions can change depending on the footprint requirement and/or the stamping process. Optionally, a bigger area of the regions 14A to 14C may improve the robustness of a mold compound arranged beneath them.

The diepad 100 may include at least one uncoined tie bar 18 arranged between two coined edge regions 14 of the bottom surface 12. During a fabrication of semiconductor devices tie bars may be configured to mechanically connect adjacent diepads of a leadframe panel as can e.g. be seen in the method of FIG. 5. In the illustrated example, the diepad 100 may include a first tie bar 18A arranged between the first coined edge region 14A and the third coined edge region 14C as well as a second tie bar 18B arranged between the second coined edge region 14B and the third coined edge region 14C. The coined edge regions 14A to 14C may surround the uncoined region 16 at three sides of the diepad 100, except at the locations of the uncoined tie bars 18A and 18B.

As can be seen from the exemplary view of the bottom surface 12 shown in FIG. 1C, each of the tie bars 18A and 18B may include a first section 20A having a first width w₁ measured in the x-direction and a second section 20B having a second width w₂ measured in the x-direction smaller than the first width w₁. The first section 20A of the respective tie bar 18 may be arranged inside the area (or footprint) of the top surface 10, while the second section 20B of the respective tie bar 18 may extend beyond the area of the top surface 10. When measured in the y-direction, a dimension d_{TB} of the first section 20A of the first tie bar 18A arranged between the two coined edge regions 14A and 14C may equal the dimension d_{A}. The same may hold true for the first section 20A of the second tie bar 18B and the dimension d_{B}.

The diepad 100 may optionally include an opening 22 which may extend through the diepad 100 in the z-direction from the top surface 10 to the bottom surface 12. In the illustrated example, the opening 22 may have the shape of a rectangle. In further examples, the shape of the opening 22 may differ and may be round, circular, elliptical, quadratic, etc. The bottom surface 12 of the diepad 100 may include a coined region 24 surrounding the opening 22.

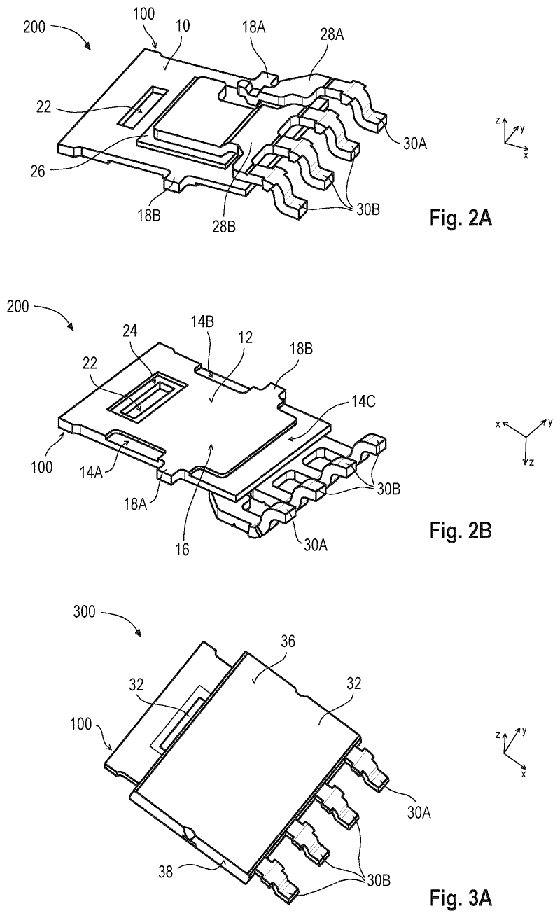

Referring now to FIGS. 2A and 2B, different views of a semiconductor device 200 in accordance with the disclosure are shown. The semiconductor device 200 may include a diepad 100 which may be similar or identical to the diepad 100 of FIG. 1. The semiconductor device 200 may further include one or more semiconductor dies 26 mounted on the top surface 10 of the diepad 100 as well as one or more electrical connection elements 28 connected to the semiconductor die 26.

In general, the semiconductor dies described herein may be manufactured from an elemental semiconductor material (e.g. Si) or from a wide band gap semiconductor material or a compound semiconductor material (e.g. SiC, GaN, SiGe, GaAs). The semiconductor dies may be of arbitrary types and may include integrated circuits with active electronic components and/or passive electronic components. The integrated circuits may be designed as logic integrated circuits, analog integrated circuits, mixed signal integrated circuits, power integrated circuits, memory circuits, integrated passives, etc. Note that, throughout this description, the terms “die”, “semiconductor die”, “chip”, “semiconductor chip” may be used interchangeably.

In particular, the semiconductor die 26 may be a power semiconductor die. In this context, the term “power semiconductor die” may refer to a semiconductor die providing at least one of high voltage blocking or high current-carrying capabilities. A power semiconductor die may be configured for high currents having a maximum current value of a few Amperes, such as e.g. 10A, or a maximum current value of up to or exceeding 100 A. Similarly, voltages associated with such current values may have values of a few Volts to a few tens or hundreds or even thousands of Volts, such as e.g. about 1200V, about 1600V, about 2400V, or the like. Power semiconductor dies may be used in any kind of power application like e.g. MOSFETs (Metal Oxide Semiconductor Field Effect Transistors), half bridge circuits, power modules including a gate driver, etc. For example, power semiconductor dies may include or may be part of a power device like e.g. a power MOSFET, an LV (low voltage) power MOSFET, a power IGBT (Insulated Gate Bipolar Transistor), a power diode, a superjunction power MOSFET, etc.

In the illustrated example, the semiconductor device 200 may include an exemplary number of two electrical connection elements 28A and 28B implemented as clips. The clips 28A, 28B may include or may be made of a metal or a metal alloy. A core material and/or a plating material of the clips 28A, 28B may be similar or equal to the materials described in connection with the diepad 100 of FIG. 1. The first clip 28A may contact one or more electrical contacts of the semiconductor die 26 arranged on the top surface of the semiconductor die 26 and may exemplarily include a single lead or pin 30A. In a similar fashion, the second clip 28B may contact one or more electrical contacts of the semiconductor die 26 arranged on the top surface of the semiconductor die 26 and may include an exemplary number of three leads or pins 30B.

In a non-limiting example, the semiconductor die 26 may include or may correspond to a power transistor having a drain electrode arranged on the bottom surface of the semiconductor die 26 facing the top surface 10 of the diepad 100 as well as a source electrode and a gate electrode arranged on the top surface of the semiconductor die 26 facing away from the top surface 10 of the diepad 100. In such case of a vertical power transistor, the drain electrode may be electrically connected to the diepad 100, the source electrode may be electrically connected to the second clip 28B and the gate electrode may be electrically connected to the first clip 28A. The electrodes of the power transistor may thus be accessible via the diepad 100 and the leads 30A, 30B.

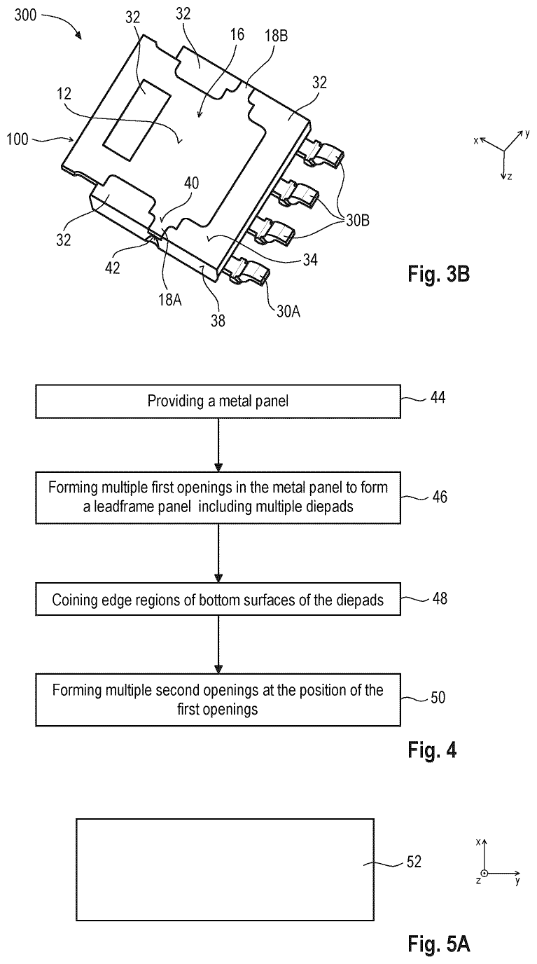

Referring now to FIGS. 3A and 3B, different views of a semiconductor device 300 in accordance with the disclosure are shown. The semiconductor device 300 may include some or all features of the semiconductor device 200 of FIG. 2. The semiconductor device 300 may include an encapsulation material 32 at least partially encapsulating the diepad 100, the semiconductor die 26 and the clips 28A, 28B. For example, the encapsulation material 32 may include or may be made of at least one of an epoxy, a filled epoxy, a glass fiber filled epoxy, an imide, a thermoplast, a thermoset polymer, a polymer blend, a laminate, a mold compound, or the like. Various techniques may be used for encapsulating components in the encapsulation material 32, for example at least one of compression molding, injection molding, powder molding, liquid molding, map molding, or the like. In the illustrated example, the encapsulation material 32 may form an encapsulation body having a bottom surface 34, an opposing top surface 36 and side surfaces 38 connecting the bottom surface 34 and the top surface 36. The semiconductor device 300 may also be referred to as semiconductor package.

The uncoined region 16 of the diepad 100 may be uncovered by the encapsulation material 32, while the coined edge regions 14A to 14C of the diepad 100 may be at least partially covered by the encapsulation material 32. In the illustrated example, the coined edge regions 14A to 14C may be fully covered by the encapsulation material 32 and are thus not visible in the view of FIG. 3B. The uncoined region 16 of the diepad 100 and the bottom surface 34 of the encapsulation material 32 may be substantially coplanar, i.e. they may be arranged in a common plane. One or more of the side surfaces 38 of the encapsulation material 32 may be arranged substantially perpendicular to the bottom surface 34 and the top surface 36 of the encapsulation material 32. In the illustrated example, the side surfaces 38 of the encapsulation material 32 may be arranged in the x-z-plane, while the bottom surface 34 and the top surface 36 of the encapsulation material 32 may be arranged in the x-y-plane.

Each of the tie bars 18A and 18B may be at least partially uncovered by the encapsulation material 32. In the illustrated example, a bottom surface 40 and a side surface 42 of a respective tie bar 18 may be uncovered by the encapsulation material 32. The side surface 38 of the encapsulation material 32 and the side surface 42 of the tie bar 18 may be substantially coplanar, i.e. they may be arranged in a common plane. In the illustrated example, the side surface 42 of a respective tie bar 18 may be arranged in the x-z-plane.

The semiconductor device 300 and other semiconductor devices in accordance with the disclosure described herein may outperform conventional semiconductor devices. Oftentimes, the area of the bottom surface of a diepad may be dictated by footprint compatibility requirements. Furthermore, in many conventional semiconductor devices, the area of the top surface of the diepad may correspond to the area of the bottom surface of the diepad such that the mounting surface of the diepad may thus be limited to a specific mounting area. Accordingly, only semiconductor dies up to a certain size may be arranged on the diepad of a conventional semiconductor device. In contrast to this, the bottom surface 12 of the diepad 100 may include coined edge regions 14A to 14C such that the area of the top surface 10 may be larger than the area of the uncoined region 16 of the bottom surface 12. The semiconductor device may thus provide both a compatible footprint and a larger mounting area for the semiconductor die at the same time. In a non-limiting example, a diepad of a conventional semiconductor device may only accommodate semiconductor dies having a chip size of up to about 6.39 mm², while a semiconductor device in accordance with the disclosure may provide mounting areas of up to 10.5 mm², i.e. of about 64.3% more than conventional devices.

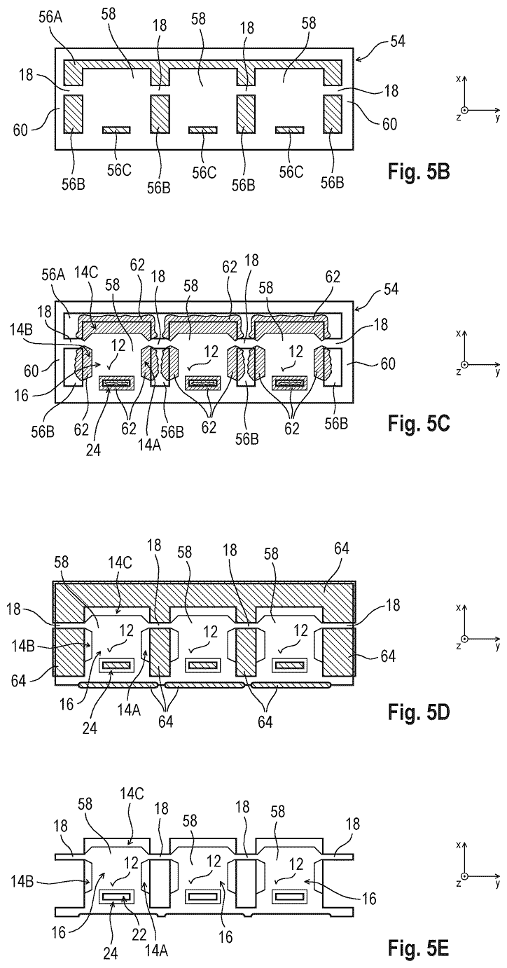

Referring now to FIG. 4, a flowchart of a method in accordance with the disclosure is illustrated. The method is described in a general manner in order to qualitatively specify aspects of the disclosure. The method may be used in a fabrication of semiconductor devices in accordance with the disclosure. In particular, the method may be applied for manufacturing one or multiple diepads as e.g. shown in FIG. 1. It is to be understood that the method may include further aspects. For example, the method may be extended by any of the aspects described in connection with other examples provided herein. For example, the method may be extended by any of the aspects described in connection with the method of FIG. 5.

In a step 44, a metal panel may be provided. In a step 46, multiple first openings may be formed in the metal panel to form a leadframe panel including multiple diepads. The multiple diepads may be arranged in a row, wherein two adjacent diepads may be separated by two first openings arranged side by side and connected by a tie bar between the two first openings. In a step 48, edge regions of bottom surfaces of the diepads may be coined, wherein material of the diepads may be pressed into an area of the first openings. In a step 50, multiple second openings may be formed at the position of the multiple first openings so as to remove the material pressed into the area of the first openings, wherein each second opening may be wider than the first openings, wherein the two adjacent diepads may still be connected by the tie bar.

Referring now to FIGS. 5A to 5E, a further method in accordance with the disclosure is described. The method of FIG. 5 may be seen, at least in parts, as a more detailed version of the method of FIG. 4. For example, the method of FIG. 5 may be used for manufacturing the diepad 100 of FIG. 1.

In FIG. 5A, a metal panel (or metal sheet) 52 may be provided. The metal panel 52 may include or may be made of a metal or a metal alloy. For example, the metal panel 52 may include a core material including at least one of copper, copper alloy, aluminum, aluminum alloy, or the like. Optionally, the metal panel 52 may be plated with at least one plating material which may, for example, include at least one of nickel, nickel-phosphorous, nickel-nickel-phosphorous, copper, silver, or the like. The step of FIG. 5A may correspond to the step 44 of FIG. 4.

In FIG. 5B, multiple first openings 56 may be formed in the metal panel 52 to form a leadframe panel 54. For example, the material at the position of the first openings 56 may be removed by a cutting process. In the illustrated example, the first openings 56 are indicated by hatched areas. The obtained leadframe panel 54 may include a peripheral frame 60 and multiple rows of diepads 58 connected to opposite sides of the peripheral frame 60. In the illustrated case, only one row of diepads 58 extending in the y-direction and including an exemplary number of three diepads 58 is shown for the sake of simplicity. In practice, the leadframe panel 54 may include multiple rows of diepads 58 arranged in parallel, wherein the number of diepads included in a row may be larger than three, for example up to a few dozens.

Diepads 58 arranged in a same row of diepads 58 may be connected via tie bars 18. In this regard, adjacent diepads 58 may be separated by two first openings 56A, 56B arranged side by side and connected by a tie bar 18 between the two first openings 56A, 56B. A diepad 58 in a row of diepads 58 may include two tie bars 18 arranged on opposite sides of the diepad 58. The innermost and outermost diepad 58 may be connected to the peripheral frame 60 via a tie bar 18 and to an adjacent diepad 58 via an opposing tie bar 38. The other diepads 58 of a row may be connected to two adjacent diepads 58 of the row of diepads 58 via two opposing tie bars 18. The step of FIG. 5B may correspond to the step 46 of FIG. 4.

In FIG. 5C, the leadframe panel 54 may be coined by means of a coining tool. During the coining process a puncher of the coining tool may be moved in the z-direction towards the leadframe panel 54 and at least partially coin the leadframe panel 54. Material 62 of the diepads 58 may be pressed into one or more areas of the first openings 56A to 56C. In the illustrated example, the material 62 pressed into the first openings 56 and the areas of the diepads 58 from which this material originates are indicated by hatched areas. After performing the coining process each of the diepads 58 may include coined edge regions 14A to 14C and an uncoined region 16 on its bottom surface 12. The coined and uncoined regions of the diepads 58 may be similar to respective regions previously described in connection with FIG. 1. The step of FIG. 5C may correspond to the step 48 of FIG. 4.

In FIG. 5D, multiple second openings 64 may be formed at the position of the multiple first openings 56A to 56C so as to remove the material 62 pressed into the area of the first openings 56A to 56C. For example, the material 62 may be removed by a cutting process similar to FIG. 5B. In particular, each second opening 64 may be wider than an associated one of the first openings 56A to 56C. Note that at least a portion of the coined edge regions 14A to 14C remains when the material 62 is removed by the cutting process. Furthermore, the cutting process does not necessarily affect the tie bars 18 in that two adjacent diepads 58 are still connected by the tie bar 18 after the cutting process has been performed. The step of FIG. 5D may correspond to the step 50 of FIG. 4.

In FIG. 5E, the arrangement is shown after the cutting process of FIG. 5D has been performed. The diepads 58 may still be connected by the tie bars 18. The side walls of each diepad 58 may be substantially perpendicular to the bottom surface 12 of the respective diepad 58, and the side walls may be free from the material 62. Each of the manufactured diepads 58 may be similar to the diepad 100 of FIG. 1 and may include some or all features of the diepad 100 as previously described. In particular, the tie bars 18 may be uncoined and arranged between two coined edge regions of the bottom surface 12. When viewed in the z-direction the tie bars 18 may include a first section having a first width and a second section having a second width smaller than the first width. The first section of a respective tie bar 18 may be arranged inside the area of the top surface 10 of the diepad 18, and the second section of the tie bar 18 may extend beyond the area of the top surface 10.

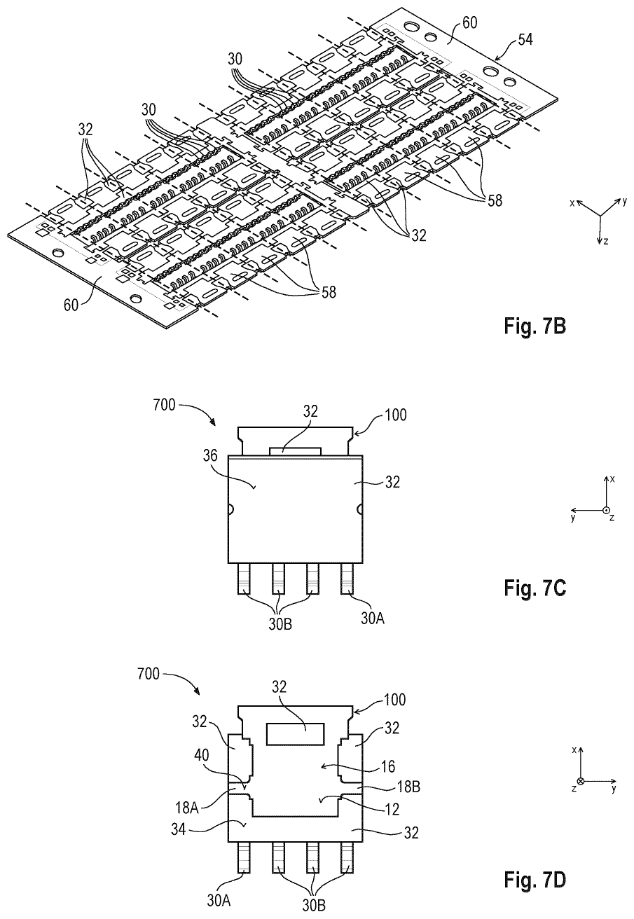

Referring now to FIG. 6, a flowchart of a method in accordance with the disclosure is illustrated. The method is described in a general manner in order to qualitatively specify aspects of the disclosure. The method may be used in the fabrication of semiconductor devices in accordance with the disclosure as previously described. It is to be understood that the method may include further aspects. For example, the method may be extended by any of the aspects described in connection with other examples described herein.

In a step 66, a leadframe panel including multiple diepads arranged in multiple rows may be provided. Each diepad may include a top surface and a bottom surface. The bottom surface of each diepad may include a coined edge region and an uncoined region. An area of the top surface may be larger than an area of the uncoined region of the bottom surface. In a step 68, multiple semiconductor dies may be mounted on the top surfaces of the diepads. In a step 70, multiple clips may be attached on top of the semiconductor dies. In a step 72, an encapsulation process may be performed, wherein multiple bars made of an encapsulation material may be formed, wherein each bar may encapsulate a row of diepads. In a step 74, the multiple bars may be singulated into multiple semiconductor packages.

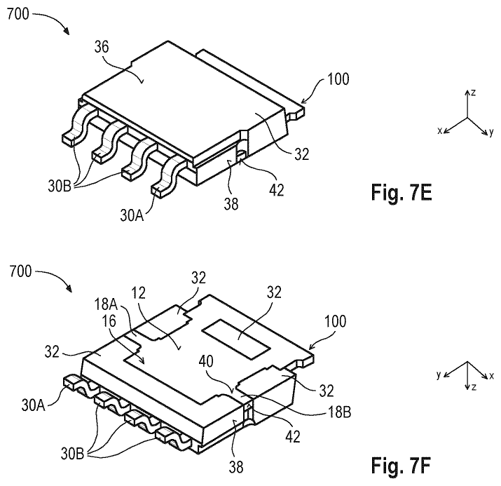

Referring now to FIGS. 7A to 7F, a further method in accordance with the disclosure is described, which may be, at least in parts, similar to the method of FIG. 6. For example, the method of FIG. 7 may be used for manufacturing one or multiple of the semiconductor devices 200 and 300 of FIGS. 2 and 3.

In FIG. 7A, a leadframe panel 54 including multiple diepads 58 arranged in multiple rows may be provided. Semiconductor dies 26 may be arranged on mounting surfaces of the diepads 58. The leadframe panel 54 may include a peripheral frame 60, wherein the rows of diepads 58 may be connected to opposite sides of the peripheral frame 60. The rows of diepads 58 may be partially separated by gaps 76. An enlarged detail of the leadframe panel 54 is shown in a dashed rectangle. As can be seen from this detail, the rows of diepads 58 of FIG. 7A may be similar to the rows of diepads 58 shown in FIG. 5E. Associated features have been previously described in connection with FIG. 5, to which reference is made herewith. In particular, each diepad 58 may include a top surface 10 and a bottom surface 12, wherein the bottom surface 12 may include coined edge regions 14A to 14C and an uncoined region 16. An area of the top surface 10 may be larger than an area of the uncoined region 16 of the bottom surface 12. The step of FIG. 7A may correspond to the steps 66 and 68 of FIG. 6.

In a further step (not illustrated), clips may be attached and electrically connected to the semiconductor dies 26. This step may correspond to the step 70 of FIG. 6. For example, the clips may be similar to the clips 28A and 28B described in connection with FIGS. 2A and 2B. In particular, the clips may be formed as a batch clip frame including a plurality of clips 28A, 28B. Such batch clip frames may be arranged in the gaps 76 and the included clips may be attached to the semiconductor dies 26 arranged at both sides of the respective gap 76. In the illustrated example, four batch clip frames may be arranged in the four gaps 76 such that all semiconductor dies 26 may be electrically coupled to clips similar to FIG. 2.

In a further step (not illustrated), a reflow process may be performed for connecting the batch clip frames or clips to the semiconductor dies 26. In addition, optional flux clean and plasma clean processes may be performed.

In a further step (not illustrated), an encapsulation process may be performed. This step may correspond to the step 72 of FIG. 6. For example, multiple bars made of an encapsulation material may be formed in a molding process, wherein each molded bar may encapsulate a row of diepads. In addition, a post mold cure (PMC) process may be performed.

In a further step (not illustrated), one or multiple dambars of the arrangement may be cut. Dambars may be used in leadframe designs to facilitate a molding or encapsulation act and further to provide support for leads. In this regard, the dambars may be arranged between adjacent leads. During the encapsulation act the dambar may be configured to function as a clamping surface for the edges of the mold tool and as a barrier to prevent leakage or flashing of the mold material from the mold tool onto the leads. After the encapsulation act the dambar may be removed so that the leads may be physically and/or electrically individualized depending on their respective functionality.

In a further step (not illustrated), at least one of a deflashing or plating process may be performed.

In a further step (not illustrated), the leads of the clips 28A, 28B may be trimmed and/or formed.

In FIG. 7B, the arrangement processed by the previously described steps is shown, but rotated by 180 degrees. The arrangement may include a plurality of encapsulated elements arranged in rows, wherein each element may include a diepad, a semiconductor die and clips. The arrangement including multiple bars made of the encapsulation material may be singulated into multiple semiconductor devices (or semiconductor packages). An exemplary singulation of the arrangement is indicated by dashed lines.

In FIGS. 7C to 7F, different views of a semiconductor device 700 obtained by the singulation process of FIG. 7B are shown. In particular, the semiconductor device 700 may include some or all features of the semiconductor device 300 of FIG. 3. These features have been previously described in connection with FIG. 3, to which reference is made herewith.

### EXAMPLES

In the following, semiconductor devices and methods in accordance with the disclosure are described by means of examples.

Example 1 is a semiconductor device, comprising: a diepad including a top surface and a bottom surface; and a semiconductor die mounted on the top surface of the diepad, wherein the bottom surface of the diepad comprises at least two coined edge regions and an uncoined region, wherein the diepad comprises an uncoined tie bar arranged between two coined edge regions of the bottom surface, and wherein an area of the top surface is larger than an area of the uncoined region of the bottom surface.

Example 2 is a semiconductor device according to Example 1, wherein in a top view of the bottom surface the tie bar includes a first section having a first width and a second section having a second width smaller than the first width.

Example 3 is a semiconductor device according to Example 2, wherein in the top view of the bottom surface: the first section of the tie bar is arranged inside the area of the top surface, and the second section of the tie bar extends beyond the area of the top surface.

Example 4 is a semiconductor device according to any of the preceding Examples, further comprising: an encapsulation material at least partially encapsulating the diepad and the semiconductor die, wherein the uncoined region of the bottom surface is uncovered by the encapsulation material.

Example 5 is a semiconductor device according to Example 4, wherein: the coined edge region of the bottom surface is at least partially covered by the encapsulation material, and the tie bar is at least partially uncovered by the encapsulation material.

Example 6 is a semiconductor device according to Example 4 or 5, wherein the uncoined region of the bottom surface and a bottom surface of the encapsulation material are substantially coplanar.

Example 7 is a semiconductor device according to any of Examples 4 to 6, wherein a side surface of the encapsulation material is arranged substantially perpendicular to a bottom surface of the encapsulation material and a top surface of the encapsulation material.

Example 8 is a semiconductor device according to any of Examples 4 to 7, wherein a side surface of the encapsulation material and the tie bar are substantially coplanar.

Example 9 is a semiconductor device according to any of the preceding Examples, wherein the at least two coined edge regions surround the uncoined region at two or more sides of the diepad.

Example 10 is a semiconductor device according to any of the preceding Examples, wherein the at least two coined edge regions surround the uncoined region at two or more sides of the diepad, except at the location of the tie bar.

Example 11 is a semiconductor device according to any of the preceding Examples, wherein the bottom surface of the diepad comprises a first coined edge region arranged at a first side of the diepad and a second coined edge region arranged at a second side of the diepad opposite the first side.

Example 12 is a semiconductor device according to Example 11, wherein the bottom surface of the diepad comprises a third coined edge region arranged at a third side of the diepad connecting the first side and the second side of the diepad.

Example 13 is a semiconductor device according to any of Examples 2 to 12, wherein a dimension of the first section of the tie bar arranged between the two coined edge regions equals a dimension of the two coined edge regions.

Example 14 is a semiconductor device according to any of the preceding Examples, wherein a thickness of the coined edge region is in a range from 60% to 90% of a thickness of the uncoined region.

Example 15 is a method, comprising: providing a metal panel; forming multiple first openings in the metal panel to form a leadframe panel comprising multiple diepads, wherein the multiple diepads are arranged in a row, wherein two adjacent diepads are separated by two first openings arranged side by side and connected by a tie bar between the two first openings; coining edge regions of bottom surfaces of the diepads, wherein material of the diepads is pressed into an area of the first openings; and forming multiple second openings at the position of the multiple first openings so as to remove the material pressed into the area of the first openings, wherein each second opening is wider than the first openings, wherein the two adjacent diepads are still connected by the tie bar.

Example 16 is a method according to Example 15, wherein the tie bar is uncoined and arranged between two coined edge regions of the bottom surface.

Example 17 is a method according to Example 15 or 16, wherein at least a portion of the coined edge regions remains when the material pressed into the area of the first openings is removed.

Example 18 is a method according to any of Examples 15 to 17, wherein, after forming the multiple second openings: a side wall of each diepad is substantially perpendicular to the bottom surface of the respective diepad, and the side wall is free from material pressed into the area of the first openings.

Example 19 is a method according to any of Examples 15 to 18, wherein: the leadframe panel comprises a peripheral frame and multiple rows of diepads, wherein the rows of diepads are connected to opposite sides of the peripheral frame, and diepads arranged in a same row of diepads are connected via tie bars.

Example 20 is a method according to Example 19, wherein: a diepad in a row of diepads comprises two tie bars arranged on opposite sides of the diepad, and the diepad is connected to two adjacent diepads of the row of diepads via the two tie bars.

Example 21 is a method according to any of Examples 15 to 20, wherein in a top view of the bottom surface the tie bar includes a first section having a first width and a second section having a second width smaller than the first width.

Example 22 is a method according to Example 21, wherein in the top view of the bottom surface: the first section of the tie bar is arranged inside the area of the top surface, and the second section of the tie bar extends beyond the area of the top surface.

Example 23 is a method, comprising: providing a leadframe panel comprising multiple diepads arranged in multiple rows, wherein: each diepad includes a top surface and a bottom surface, the bottom surface of each diepad comprises a coined edge region and an uncoined region, and an area of the top surface is larger than an area of the uncoined region of the bottom surface; mounting multiple semiconductor dies on the top surfaces of the diepads; attaching multiple clips on top of the semiconductor dies; performing an encapsulation process, wherein multiple bars made of an encapsulation material are formed, wherein each bar encapsulates a row of diepads; and singulating the multiple bars into multiple semiconductor packages.

As employed in this description, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the words “over” and “on” used with regard to e.g. a material layer formed or located “over” or “on” a surface of an object may be used herein to mean that the material layer may be located (e.g. formed, deposited, etc.) “directly on”, e.g. in direct contact with, the implied surface. The words “over” and “on” used with regard to e.g. a material layer formed or located “over” or “on” a surface may also be used herein to mean that the material layer may be located (e.g. formed, deposited, etc.) “indirectly on” the implied surface with e.g. one or more additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the previous instances. In addition, the articles “a” and “an” as used in this application and the appended claims may generally be construed to mean “one or more” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include a step of providing the component in a suitable manner, even if such step is not explicitly described or illustrated in the figures.

Although the disclosure has been shown and described with respect to one or more implementations, equivalent alterations and modifications will occur to others skilled in the art based at least in part upon a reading and understanding of this description and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor device, comprising:
a diepad including a top surface and a bottom surface; and
a semiconductor die mounted on the top surface of the diepad,
wherein the bottom surface of the diepad comprises at least two coined edge regions and an uncoined region,
wherein a coined edge region of the bottom surface continuously extends along multiple sides of the diepad,
wherein the diepad comprises an uncoined tie bar arranged between two coined edge regions of the bottom surface, and
wherein an area of the top surface is larger than an area of the uncoined region of the bottom surface.

2. The semiconductor device of claim 1, wherein in a top view of the bottom surface the tie bar includes a first section having a first width and a second section having a second width smaller than the first width.

3. The semiconductor device of claim 2, wherein in the top view of the bottom surface:
the first section of the tie bar is arranged inside the area of the top surface, and
the second section of the tie bar extends beyond the area of the top surface.

4. The semiconductor device of claim 1, further comprising:
an encapsulation material at least partially encapsulating the diepad and the semiconductor die, wherein the uncoined region of the bottom surface is uncovered by the encapsulation material.

5. The semiconductor device of claim 4, wherein:
the coined edge region of the bottom surface is at least partially covered by the encapsulation material, and
the tie bar is at least partially uncovered by the encapsulation material.

6. The semiconductor device of claim 4, wherein the uncoined region of the bottom surface and a bottom surface of the encapsulation material are substantially coplanar.

7. The semiconductor device of claim 4, wherein a side surface of the encapsulation material is arranged substantially perpendicular to a bottom surface of the encapsulation material and a top surface of the encapsulation material.

8. The semiconductor device of claim 4, wherein a side surface of the encapsulation material and the tie bar are substantially coplanar.

9. The semiconductor device of claim 1, wherein the at least two coined edge regions surround the uncoined region at two or more sides of the diepad.

10. The semiconductor device of claim 1, wherein the at least two coined edge regions surround the uncoined region at two or more sides of the diepad, except at the location of the tie bar.

11. The semiconductor device of claim 1, wherein the bottom surface of the diepad comprises a first coined edge region arranged at a first side of the diepad and a second coined edge region arranged at a second side of the diepad opposite the first side.

12. The semiconductor device of claim 11, wherein the bottom surface of the diepad comprises a third coined edge region arranged at a third side of the diepad connecting the first side and the second side of the diepad.

13. The semiconductor device of claim 2, wherein a dimension of the first section of the tie bar arranged between the two coined edge regions equals a dimension of the two coined edge regions.

14. The semiconductor device of claim 1, wherein a thickness of the coined edge region is in a range from 60% to 90% of a thickness of the uncoined region.

15. A method, comprising:
providing a leadframe panel comprising multiple diepads arranged in multiple rows, wherein:
each diepad includes a top surface and a bottom surface,
the bottom surface of each diepad comprises at least two coined edge regions and an uncoined region,
a coined edge region of the bottom surface continuously extends along multiple sides of the diepad,
each diepad comprises an uncoined tie bar arranged between two coined edge regions of the bottom surface, and
an area of the top surface is larger than an area of the uncoined region of the bottom surface;
mounting multiple semiconductor dies on the top surfaces of the diepads;
attaching multiple clips on top of the semiconductor dies;
performing an encapsulation process, wherein multiple bars made of an encapsulation material are formed, wherein each bar encapsulates a row of diepads; and
singulating the multiple bars into multiple semiconductor packages.
